(19) United States
(12) Patent Application Publication
(10) Pub. No.: US 2001/0017422 A1
(43) Pub. Date: Aug. 30, 2001

(54) Semiconductor device with copper-based wiring lines and method of fabricating the same

(76) Inventor: Noriaki Oda, Tokyo (JP)

Correspondence Address: SUGHRUE, MION, ZINN, MACPEAK & SEAS, PLLC, 2100 Pennsylvania Avenue, N.W., Washington, DC, 20037-3202, US

(21) Appl. No.: 09/739,620

(22) Filed: Dec. 20, 2000

(30) Foreign Application Priority Data
Dec. 21, 1999 (JP) 362853/1999

(51) Int. Cl. H01L 23/48; H01L 21/4763; H01L 21/44

(52) U.S. Cl. 257/768; 257/751; 438/687; 438/629; 438/643

(57) ABSTRACT

A method of fabricating a semiconductor device is provided, which decreases the parasitic wiring capacitance among adjoining Cu-based wiring lines is provided and which prevents the oxidation of Cu-based wiring lines and the diffusion of the Cu atoms existing in the wiring lines. This method comprises the steps of (a) forming a first dielectric layer over a surface of a substrate; (c) forming a trench in the first dielectric layer; (d) covering an inner surface of the trench with a first nitride of refractory metal; (e) forming a Cu-based conductor on the first nitride of refractory metal in the trench; (f) covering a top surface of the conductor in the trench with a second nitride of refractory metal; (g) polishing the first dielectric layer until a polished surface of the first dielectric layer is approximately in a same level as a surface of the second nitride of refractory metal that covers the top surface of the conductor in the trench; and (h) forming a second dielectric layer on the polished surface of the first dielectric layer to cover the surface of the second nitride of refractory metal in the trench. The Cu-based conductor is entirely covered with the first nitride of refractory metal and the second nitride of refractory metal in the trench. The conductor, the first nitride of refractory metal, and the second nitride of refractory metal constitute a Cu-based wiring line.

### BACKGROUND OF THE INVENTION

1. Field of the Invention

The present invention relates to a semiconductor device and a method of fabricating the same and more particularly, to a semiconductor device comprising copper (Cu) based wiring lines that decreases the parasitic wiring capacitance due to adjoining wiring lines to thereby raise the operation speed of circuits in the device, and a method of fabricating the device

2. Description of the Related Art

An example of the conventional semiconductor devices of this type has wiring lines each comprising a dielectric having a wiring trench, a tantalum nitride (TaN) layer covering the inner walls of the trench, a Cu-based conductor formed on the TaN layer to fill the trench, and a silicon dioxide (SiO₂) layer covering the top face of the conductor exposed from the trench.

Specifically, an interlayer dielectric layer is formed on the surface of a substrate. An etch stop layer is formed on the interlayer dielectric layer. A SiO₂ layer is formed on the etch stop layer by a plasma-enhanced chemical Vapor Deposition (CVC) process, which is termed the plasma oxide layer. Wiring trenches for the Cu-based conductors are formed in the plasma oxide and the underlying etch stop layer. A TaN layer is deposited to cover the inner walls of the respective trenches. Cu-based conductors are formed on the TaN layers in the respective trenches to fill the same. SiO₂ is deposited to cover the exposed top faces of the respective conductors.

With the above-described conventional semiconductor device, the deposited SiO₂ contacts closely the top faces of the Cu-based conductors in the trenches and therefore, Cu atoms existing in the conductors tend to diffuse into the overlying SiO₂. Thus, there arises a problem that current leakage between the adjoining Cu-based conductors increases, causing malfunction or incorrect operation of the circuits in the device.

Also, the C-based conductors are easily oxidized and thus, there arises another problem that the electrical resistance of the wiring line increases, forming a cause of the malfunction of the circuits in the device.

To solve these problems, an improved wiring structure is developed and disclosed by the Japanese Non-Examined Patent Publication No. 9-275138 published in 1997. In this improved structure, trenches are formed in a lower interlayer dielectric layer. A titanium nitride (TiN) layer (which serves as a barrier metal layer) is formed to cover the inner walls of each trench. Cu-based conductors are formed on the TiN layer to fill the respective trenches, in other words, the conductors are buried in the respective trenches. The top faces of the conductors, which are not covered with the TiN layer, are covered with a silicon nitride (SiN) layer. An upper interlayer dielectric layer is formed on the lower interlayer dielectric layer to cover the SiN layer.

The reason why the top faces of the Cu-based conductors are covered with the SiN layer is (a) to prevent the electrical resistance of the conductors from increasing due to their oxidation, (b) to prevent the leakage current among the adjoining wiring lines from increasing, and (c) to prevent the dielectric strength of the wiring lines from degrading Because of this measure, the characteristic fluctuation of the semiconductor elements (e.g., transistors) provided in the semiconductor device with the improved wiring structure is suppressed.

With the improved wiring structure disclosed in the Publication No. 9-275138, however, the SiN layer has a relative dielectric constant as high as 7 to 10. Thus, the electric flux lines interconnecting the top faces of the adjoining wiring lines increase, thereby causing a problem that the unwanted, parasitic wiring capacitance is raised and the operation speed of the circuits is lowered.

Moreover, there is another problem that the adhesion strength between the SiN layer and the Cu-based conductors is poor.

### SUMMARY OF THE INVENTION

Accordingly, an object of the present invention is to provide a semiconductor device that decreases the parasitic wiring capacitance among adjoining Cu-based wiring lines, and a method of fabricating the device.

Another object of the present invention is to provide a semiconductor device that prevents the oxidation of Cu-based wiring lines and the diffusion of the Cu atoms existing in the wiring lines into an adjoining material or materials, and a method of fabricating the device.

Still another object of the present invention is to provide a semiconductor device that enables higher-speed operation of the semiconductor device, and a method of fabricating the device.

A further object of the present invention is to provide a semiconductor device that prevents malfunction or incorrect operation of the circuits provided in the semiconductor device, and a method of fabricating the device.

A still further object of the present invention is to provide a semiconductor device that makes it possible to contact closely a diffusion barrier material with Cu-based wiring lines, and a method of fabricating the device.

A more further object of the present invention is to provide a semiconductor device that suppresses effectively the electromigration phenomenon, and a method of fabricating the device.

The above objects together with others not specifically mentioned will become clear to those skilled in the art from the following description.

According to a first aspect of the present invention, a semiconductor device is provided, which is comprised of:

(a) a substrate having a surface;

(b) a dielectric formed over the surface of the substrate; and

(c) a wiring line buried in the first dielectric layer;

the wiring line including a cu-based conductor and a first cover layer covering an outer surface of the conductor;

the first cover layer being made of refractory metal nitride.

With the semiconductor device according to the first aspect of the present invention, the wiring line includes the cu-based conductor and the first cover layer covering the outer surface of the conductor The first cover layer is made of refractory metal nitride. As a result, the parasitic wiring capacitance among the adjoining Cu-based wiring lines is decreased even if the distance between the wiring lines is shortened, which enables higher-speed operation of the semiconductor device.

At the same time as this, since the oxidation of the Cu-based wiring line is effectively prevented, the electrical resistance of the wiring line does not increase. Also, the diffusion of the Cu atoms existing in the wiring conductor into an adjoining material or materials is effectively prevented and therefore, the leakage current among the adjoining wiring lines is suppressed or prevented. Thus, the malfunction or incorrect operation of the circuits provided in the semiconductor device is prevented.

Moreover, since the first cover layer is made of refractory metal nitride, the first cover layer serving as a diffusion barrier layer can be contacted closely with the Cu-based conductor. Also, because of the same reason, the electromigration phenomenon is effectively suppressed.

In a preferred embodiment of the device according to the first aspect, the first cover layer is made of nitride of at least one selected from the group consisting of titanium (Ti), tantalum (Ta), and tungsten (W).

In another preferred embodiment of the device according to the first aspect, a second cover layer is additionally provided between the conductor and the first cover layer. The second cover layer covers partially or entirely the outer surface of the conductor. The second cover layer is made of refractory metal.

In still another preferred embodiment of the device according to the first aspect, a third cover layer is additionally provided between the conductor and the first cover layer. The third cover layer covers entirely or partially the outer surface of the conductor. The third cover layer is made of dielectric.

Preferably, the third cover layer covers the outer surface of the conductor at its each side.

In a further preferred embodiment of the device according to the first aspect, the dielectric formed over the surface of the substrate is made of inorganic material and has a relative dielectric constant ranging from 1.6 to 9. Alternately, it is preferred that the dielectric is made of organic material and has a relative dielectric constant of 1.6 to 3.

In a still further preferred embodiment of the device according to the first aspect, the wiring line has a damascene structure.

In a still further preferred embodiment of the device according to the first aspect, the dielectric in which the wiring line is buried has a composite structure comprising a first dielectric layer, an etch stop layer formed on the first dielectric layer, and a second dielectric layer formed on the etch stop layer. The bottom of the first cover layer is approximately in a same level as an upper surface of the first dielectric layer. The top of the first cover layer is approximately in a same level as an upper surface of the second dielectric layer.

It is preferred that the trench has inner side faces tilted at an angle of 70° to 85° with respect to an imaginary plane of a bottom of the trench.

According to a second aspect of the present invention, a method of fabricating a semiconductor device is provided, which is applicable to fabrication of the device according to the first aspect. This method comprises the steps of:

(a) forming a first dielectric layer over a surface of a substrate;

(c) forming a trench in the first dielectric layer;

(d) covering an inner surface of the trench with a first nitride of refractory metal;

(e) forming a Cu-based conductor on the first nitride, of refractory metal in the trench;

(f) covering a top surface of the conductor in the trench with a second nitride of refractory metal;

(g) polishing the first dielectric layer until a polished surface of the first dielectric layer is approximately in a same level as a surface of the second nitride of refractory metal that covers the top surface of the conductor in the trench; and

(h) forming a second dielectric layer on the polished surface of the first dielectric layer to cover the surface of the second nitride of refractory metal in the trench;

wherein the Cu-based conductor is entirely covered with the first nitride of refractory metal and the second nitride of refractory metal in the trench;

and wherein the Cu-based conductor, the first nitride of refractory metal, and the second nitride of refractory metal constitute a Cu-based wiring line.

With the method of fabricating a semiconductor device according to the second aspect of the present invention, it is obvious that the semiconductor device according to the first aspect can be fabricated. Also, because of substantially the same reason as the device according to the first aspect, there are the same advantages as those in the device.

In a preferred embodiment of the method according to the second aspect, the trench is formed to have inner side faces tilted an angle of 70° to 85° with respect to an imaginary plane of a bottom of the trench in the step (c).

In another preferred embodiment of the method according to the second aspect, in the step (e) of forming the Cu-based conductor on the first nitride of refractory metal in the trench, part of the conductor is deposited by sputtering and then, the remaining conductor is deposited by plating.

In a still another preferred embodiment of the method according to the second aspect, in the step (e) of forming the Cu-based conductor, the conductor is formed in such a way that the conductor has a height less than a depth of the trench.

In a further preferred embodiment of the method according to the second aspect, in the step (g) of polishing the first dielectric layer, a CMP process is used. End detection of the CMP process is performed by detection of polishing of the first dielectric layer after unnecessary second nitride of refractory metal deposited on the first dielectric layer is completely removed.

In a still further preferred embodiment of the method according to the second aspect, in the step (d) of covering the inner surface of the trench, nitride of at least one selected from the group consisting of titanium (Ti), tantalum (Ta), and tungsten (W) is used as the first nitride of refractory metal.

Furthermore, it is preferred that a step of depositing a first refractory metal layer on the inner surface of the trench is added between the step (c) of forming the trench and the step (d) of covering the inner surface of the trench. The first nitride of refractory metal is deposited on the first refractory metal layer in the step (d) The first refractory metal layer is used for forming a second cover layer that covers partially or entirely the Cu-based conductor.

In this case, it is preferred that a step of depositing a second refractory metal layer on the top surface of the conductor is further added between the step (e) of forming the Cu-based conductor and the step (f) of polishing the first dielectric layer. The second refractory metal layer is located on the top surface of the conductor in the trench. The first and second refractory metal layers form the second cover layer that covers entirely the Cu-based conductor.

In addition, preferably, a step of selectively depositing a dielectric on the first nitride of refractory metal in the trench is added between the step (d) of covering the top surface of the conductor and the step (e) of forming the Cu-based conductor. The dielectric thus deposited is located at each side of the Cu-based conductor in the trench to expose the bottom of the trench. The dielectric is used for forming a third cover layer that covers partially or entirely the Cu-based conductor.

In this case, it is preferred that the step of selectively depositing the dielectric on the first nitride of refractory metal includes a sub-step of depositing the dielectric on the first nitride of refractory metal and a sub-step of selectively etching part of the dielectric at the bottom of the trench.

The first cover layer is preferably made of nitride of at least one selected from the group consisting of titanium (Ti ), tantalum (Ta), and tungsten (W).

The first dielectric layer formed over the surface of the substrate is preferably made of inorganic material and has a relative dielectric constant ranging from 1.6 to 9. Alternately, it is preferred that the first dielectric layer is made of organic material and has a relative dielectric constant of 1.6 to 3.

### BRIEF DESCRIPTION OF THE DRAWINGS

In order that the present invention may be readily carried into effect, it will now be described with reference to the accompanying drawings.

FIG. 1 is a schematic, partial cross-sectional view showing the wiring structure of a semiconductor device according to a first embodiment of the invention.

FIGS. 2A to 2I are cross-sectional views showing the process steps of a method of fabricating the device according to the first embodiment of FIG. 1, respectively.

FIGS. 3A to 3D are cross-sectional views showing the process steps of another method of fabricating the device according to the first embodiment of FIG. 1, respectively.

FIG. 4 is a schematic, partial cross-sectional view showing the wiring structure of a semiconductor device according to a second embodiment of the invention.

FIGS. 5A to 5G are cross-sectional views showing the process steps of a method of fabricating the semiconductor device according to the second embodiment of FIG. 4, respectively.

FIG. 6 is a schematic, partial cross-sectional view showing the wiring structure of a semiconductor device according to a third embodiment of the invention.

FIGS. 7A to 7G are cross-sectional views showing the process steps of a method of fabricating the semiconductor device according to the third embodiment of FIG. 6, respectively.

FIG. 8 is a graph showing the relationship between the parasitic wiring capacitance and the wiring line pitch.

FIG. 9 is a graph showing the relationship between the tilt angle of the wiring trench and the electro migration (EM) resistance.

### DETAILED DESCRIPTION OF THE PREFERRED EMBODIMENTS

Preferred embodiments of the present invention will be described in detail below while referring to the drawings attached.

### First Embodiment

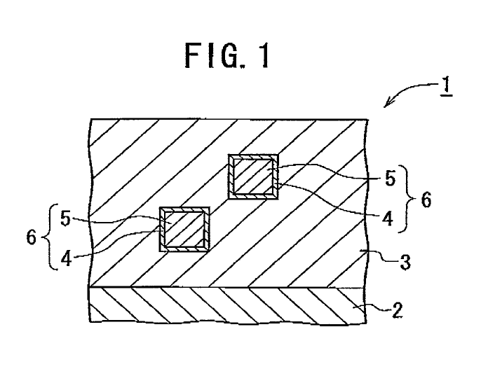

A semiconductor device according to a first embodiment of the invention has a wiring structure shown in FIG. 1.

As shown in FIG. 1, the semiconductor device 1 according to the first embodiment comprises a substrate 2, a thick dielectric 3 formed on the surface of the substrate 2, and two wiring lines 6 formed in the dielectric 3. In FIG. 1, one of the lines 6 is located in the first (i.e., lower) wiring level and the other is located in the second (i.e., upper) wiring level.

Each of the lines 6 has a Cu-based conductor 5 extending perpendicular to the paper and a cover layer 4 formed to cover the whole surface of the lines 5. Each of the conductors 5 has an approximately square cross section, here. The cover layer 4 is made of nitride of refractory metal. The entire outer surface of the conductor 5 is covered with and contacted with the refractory metal nitride cover layer 4. It may be said that the line 6 has a composite structure.

Any substrate may be used as the substrate 2 if it supports miniaturized circuitry formed thereon and is able to be produced through the so-called planer processes. For example, a semiconductor substrate such as a silicon (Si) or gallium arsenide (GaAs) substrate, a substrate having impurity-doped regions, or a chip-shaped substrate may be used for this purpose. The material of the substrate 2 is optionally selected according to the desired device characteristics or desired use. A typical material of the substrate 2 is ceramic, glass, or Si.

The dielectric 3 formed on the surface of the substrate 2, which is often called the interlayer dielectric, is preferably made of inorganic dielectric material having a relative dielectric constant ranging from 1.6 to 9 (more preferably, 1.6 to 4.5). Alternately, the dielectric 3 may be made of organic dielectric material having a relative dielectric constant ranging from 1.6 to 3. This is because the decreasing rate of the parasitic wiring capacitance can be large if the relative dielectric constant of the inorganic or organic material is in the corresponding range.

Examples of the inorganic dielectric material having a relative dielectric constant as low as 1.6 to 9 (or, 1.6 to 4.5) are SiO₂, silicon trinitride (SiN₃), phosphorsilicate glass (PSG), borosilicate glass (BSG), borophosphorsilicate glass (BPSG), fluorinated silicon oxide (SiOF), and porous silica. Examples or the organic dielectric material having a relative dielectric constant as low as 1.6 to 3 are polyimide resin, Benzo-Cyclo-Buten (BCB), and MSQ.

The dielectric 3 may include an etch stop layer according to the necessity in the fabrication process sequence of the semiconductor device 1. Any material may be used for the etch stop layer if it makes it possible to detect the endpoint of the etching process.

For example, the endpoint of the etching process may be detected by the change in etch rate occurring in the process, or by the change of the etched material(s) or component(s) in the process. Thus, any material to be etched at a different rate from the dielectric 3 or any material that generates different gaseous material due to etching from that the dielectric 3 generates. Concretely, silicon oxynitride (SiON) or silicon nitride (SiN) may be preferably used for the etch stop layer. The etch stop layer is typically 20 to 200 nm in thickness.

The thickness of the dielectric 3 is typically 0.5 μm to 50 μm. Here, two wiring lines 6 are formed in the dielectric 3; however, only the single wiring line 6 or three or more wiring lines 6 may be formed in the dielectric 3.

The Cu-based conductor 5 of each wiring line 6 is made of a Cu-based material, where the Cu-based material means a conductive material that contains at least 50 wt % of Cu as its main component. Preferably, the conductor 5 is made of a Cu-based material containing 50 wt % to 99 wt % of Cu as its main component. The Cu-based material may contain any substance that forms an alloy with Cu. For example, tin (Sn) may be used for the Cu-based material.

The conductor 5 has typically a thickness ranging from 0.1 μm to 10 μm, preferably, from 0.1 μm to 3 μm. This thickness of the conductor 5 is determined according to the overall thickness of the dielectric 3. If the thickness of the conductor 5 is less than 0.1 μm, the resistance of the conductor 5 is unsatisfactorily high. On the other hand, if the thickness of the conductor 5 is greater than 10 μm, the conductor 5 tends to exhibit a poor edge coverage property.

The cover layer 4 of the wiring line 6 may be made of nitride of any refractory metal if it has a melting point of 500° C. or higher, (preferably, it has a melting point of 1000° C. or higher, and more preferably, 1500° C. or higher). Here, the melting point means not only the melting point in the narrow sense but also the decomposition point.

As the refractory metal nitride for the cover layer 4, for example, titanium nitride (TiN, melting point: 2950° C.), vanadium nitride (VN, melting point: 2050° C.), chromium nitride (CrN, melting point: 1900° C., zirconium nitride (ZrN, melting point: 2980° C.), niobium nitride (NbN, melting point: 2578° C.), tantalum nitride (TaN, melting point: 3090° C.), or tungsten nitride (WN, melting point: 3380° C.) is preferably used. It is more preferred that TiN, TaN, or WN is used for the layer 4.

The cover layer 4 made of refractory metal nitride serves to prevent the characteristics of the Cu-based conductor 5 and the dielectric 3 from degrading even if they are subjected to heat treatment several times Also, the layer 4 itself is stable even if it is subjected to severe fabrication processes.

The cover layer 4, which forms a feature of the invention, may be termed the refractory material cover layer.

The upper and lower parts of the layer 4 that cover respectively the top and bottom surfaces of the conductor 5 may be the same in material as or different in material from the two side parts of the layer 4 that cover the two side faces of the conductor 5. It is preferred that the upper and lower parts of the layer 4 are the same in material as the side parts thereof.

The cover layer 4 may have a multilayer structure including sublayers made of different refractory metal nitrides. In this case, however, there is a disadvantage that the number of the fabrication process steps increases. Thus, it is preferred that the layer 4 has a single-layer structure,

The thickness of the cover layer 4, which may be made of a single layer or several sublayers of refractory metal nitride or nitrides, is preferably 2 nm to 50 nm. If the thickness of the layer 4 is less than 2 nm, there is a possibility that Cu-based material for the conductor 5 is unable to deposited in the process of forming the conductor 5. Also, even if the Cu-based material for the Cu line 5 is deposited, there is a possibility that the orientation property of Cu in the Cu-based material thus deposited is poor. On the other hand, if the thickness of the layer 4 is greater than 50 nm, there is a possibility that the decreasing rate of the parasitic wiring capacitance may be low.

Moreover, if the thickness of the cover layer 4 on the top surface of the conductor 5 is in the range from 2 nm to 50 nm, there is an advantage that the layer 4 (i.e., the refractory metal nitride) has a good or excellent adhesion property to the conductor 5 (i.e. the Cu-based material).

Additionally, if the two wiring lines 6 located at different levels in the dielectric 3 are electrically interconnected to each other by way of an interconnection wiring line (not shown), it is preferred that the interconnection wiring line itself is entirely covered with a layer of the same refractory metal nitride as the cover layer 4 as well.

With the semiconductor device 1 according to the first embodiment shown in FIG. 1, as seen from the above explanation, each of the wiring lines 6 is formed by the Cu-based conductor 5 and the cover layer 4 of refractory metal nitride and therefore, the parasitic wiring capacitance due to the wiring lines 6 is suppressed effectively. Thus, even if the distance between the adjoining wiring lines 6 is shortened, the increase of the parasitic wiring capacitance is kept small. As a result, the operation speed of the circuits provided on the substrate 2 and electrically connected through the wiring lines 6 is raised.

Also, the unwanted diffusion of the Cu atoms contained in the Cu-based conductor 5 into the dielectric 3 is suppressed or prevented effectively. At the same time, the unwanted oxidation of the conductor 5 is suppressed or prevented effectively. As a result, the malfunction or incorrect operation of the circuitry in the device 1 can be prevented.

Furthermore, the adhesion property between the conductor 5 and the cover layer 4 is improved and the electromigration resistance of the wiring line 6 is improved as well.

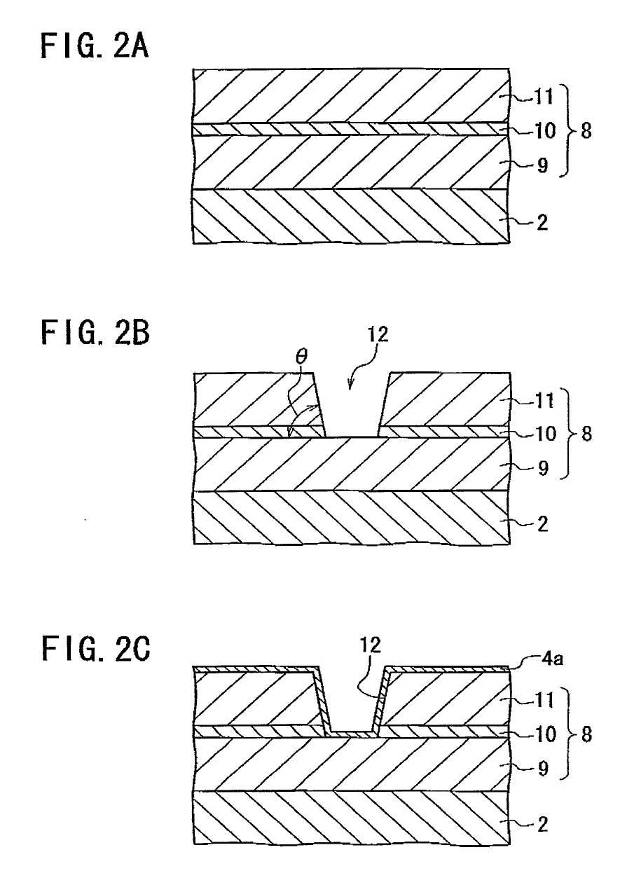

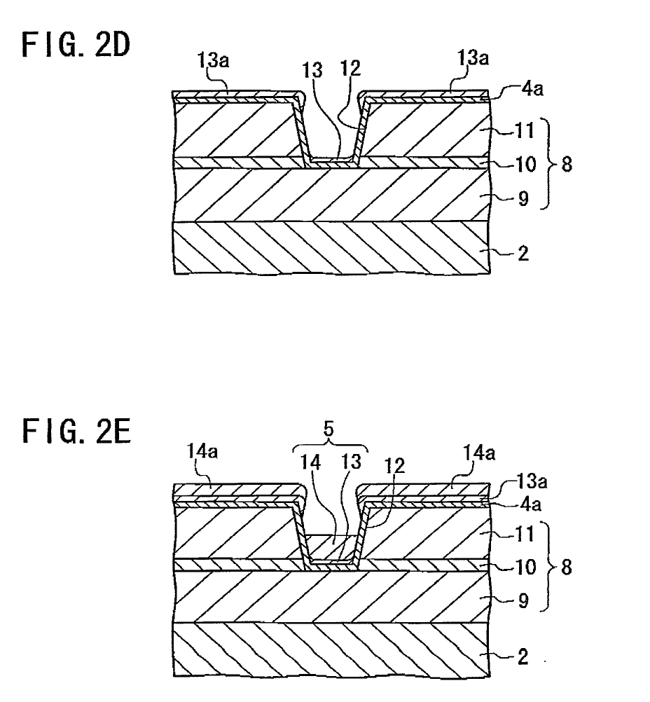

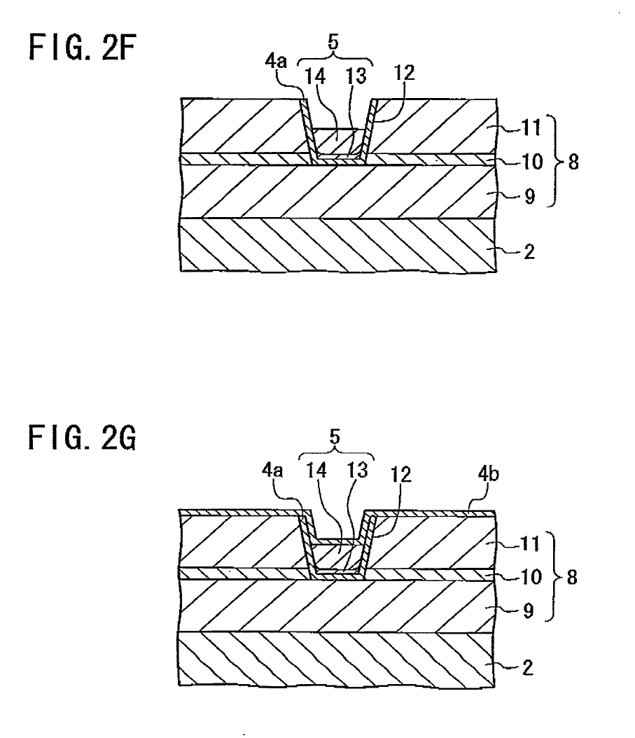

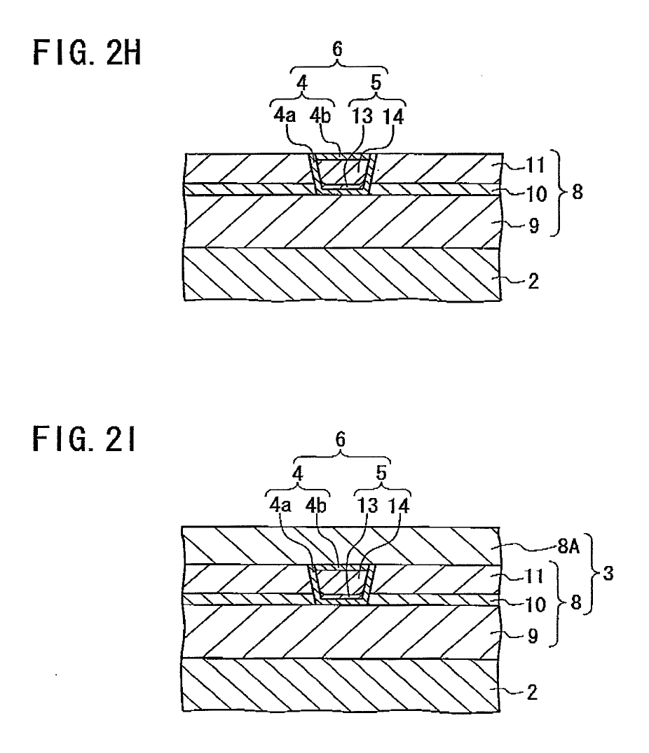

Next, a method of fabricating the semiconductor device 1 according to the first embodiment having the above-described configuration is explained below with reference to FIGS. 2A to 2I.

First, as shown in FIG. 2A, a first dielectric layer 8 made of an inorganic material is formed by way of a known process. The layer 8 may be made of any dielectric inorganic material that proves an electrical insulation property for the wiring lines 6. This process may be termed the “first dielectric layer formation step”.

To form preferably a wiring trench in the first dielectric layer 8, here, as shown in FIG. 2A, the layer 8 is constituted by the combination of an interlayer dielectric sublayer 9 formed on the surface of the substrate 2, an etch stop sublayer 10 formed on the sublayer 9, and a dielectric sublayer 11 formed on the sublayer 10. Thus, the layer 8 has a three-layer structure.

The interlayer dielectric sublayer 9 is made of any inorganic material with a resistivity of 10⁶ Ω•cm or higher. For example, SiO₂, SiOF or HSQ may be preferably used for the sublayer 9. The sublayer 9 is typically formed by a thermal oxidation process or a plasma-enhanced CVD process using SiH₄ and N₂O. However, the sublayer 9 may be formed by any other process, such as a thermal CVD, optical CVD, a plasma-enhanced CVD using tetraethoxysilane (TEOS) and oxygen (O). The sublayer 9 is typically 0.6 to 1 μm in thickness.

The etch stop sublayer 10 is provided to determine the depth of the wiring trench in the etching process of the dielectric sublayer 11. As a material of the sublayer 10, for example, SiON is typically used. The sublayer 10 is formed by the same way as the interlayer dielectric sublayer 9. The sublayer 10 is typically 0.02 to 0.06 μm in thickness.

The dielectric sublayer 11 may be made of the same material as or a different material from the interlayer dielectric sublayer 9. Typically, the sublayer 11 is made of an oxide of Si. The sublayer 11 is formed on the etch stop sublayer 10 by the same way as the interlayer dielectric sublayer 9. The sublayer 11 is typically 0.1 to 1 μm in thickness.

After the first dielectric layer 8 with the three-layer structure is formed, a wiring trench 12 is formed in the layer 8, as shown in FIG. 2B. This process may be termed the “trench formation step”.

The trench 12 may be formed by any wet or dry etching process using the photolithographic technique It is preferred that the trench 12 is formed by a dry etching process using the photolithographic technique, because a dry etching process copes with a minute trench As the dry etching process, ion-beam etching, optical etching, plasma-enhanced etching, sputter etching, or reactive ion etching may be used It is preferred that reactive ion etching is used as the dry etching process, because the adjustment or control of the etching action is easy and the productivity is high.

The depth of the trench 12, which is determined according to the design of the semiconductor device 1, is typically 0.1 to 20 μm. The width of the trench 12 is typically 0.1 to 20 μm. The bottom of the trench 12 reaches the upper surface of the interlayer dielectric sublayer 9, which is exposed from the etch stop sublayer 10 through the opening of the sublayer 10.

As shown in FIG. 2B, the trench 12 has a cross-sectional shape of inverted trapezoid, where the upper side is parallel to and longer than the lower side. In other words, the trench 12 has two opposite side faces tilted outwardly from its bottom to its top. Each of the side faces of the trench 12 has a tilt angle θ with respect to an imaginary bottom plane that is formed by extending horizontally the bottom surface of the trench 12. The tilt angle θ is preferably set at a value ranging from 70° to 85°. More preferably, the angle θ is set at a value from 75° to 85°.

After the trench 12 is formed, a refractory metal nitride layer 4a is formed on the surface of the dielectric sublayer 11 to cover the side and bottom surfaces of the trench 12, as shown in FIG. 2C. This process may be termed the “first covering step”.

The refractory metal nitride layer 4a is typically formed by a direct current (DC) sputtering process or radio frequency (RF) sputtering process. The use of one of these sputtering processes provides an advantage that less unwanted impurity is doped into the layer 4a. A magnetron sputtering process may be used for this purpose, in which there arises an advantage that the layer 4a can be formed at a high deposition rate. The thickness of the nitride layer 4a is typically 2 to 50 nm.

Subsequently, a conductive material, i.e., a Cu-based material, is deposited on the refractory metal nitride layer 4a so as to partially fill the trench 12. This process may be termed the “partial filling step”.

It is preferred that the Cu-based material is deposited by the combination of sputtering and plating processes. Specifically, as shown in FIG. 2D, a Cu-based material 13 is deposited on the nitride layer 4a in the trench 12 by a sputtering process. In this sputtering process, an unnecessary Cu-based material 13a is deposited on the nitride layer 4 existing not only outside the trench 12 but also in the vicinity of the opening top end of the trench 12. The deposited material 13 has a thickness of 2 to 50 nm in the trench 12.

Next, as shown in FIG. 2E, a Cu-based material 14a is deposited to have a thickness of 200 to 400 nm on the material 13 in the trench 12 by a plating process, where the Cu-based material 13 at the bottom of the trench 12 is used as a seed metal for plating. In this plating process, an unnecessary Cu-based material 14a is deposited on the material 13a existing not only outside the trench 12 but also in the vicinity of the opening end of the trench 12.

Here, the overall height of the deposited materials 13 and 14 in the trench 12 is approximately equal to half the depth of the trench 12. The deposited materials 13 and 14 in the trench 12 constitute the Cu-based conductor 5 or the wiring line 6.

Thus, the Cu-based conductor 5 formed by the materials 13 and 14 is deposited in the trench 12, as shown in FIG. 2E. Since the Cu-based materials 13 and 14 are deposited in the trench 12 through the two different processes, there is an advantage that the orientation property of the materials 13 and 14 are improved, thereby raising the electromigration (EM) resistance of the conductor 5.

Thereafter, the unnecessary Cu-materials 13a and 14a and the unnecessary nitride layer 4a deposited outside or near the opening end of the trench 12 are selectively removed, exposing the surface of the first dielectric layer 8 (i.e., the dielectric sublayer 11), as shown in FIG. 2F. Preferably, this removing process is carried out by a Chemical/Mechanical Polishing ((CMP) process. It is important that the exposed surface of the sublayer 11 is higher than the exposed top surface of the conductor 5 after this CMP process is completed, as shown in FIG. 2F. This process may be termed the “CMP or polishing step”.

Furthermore, as shown in FIG. 2G, a refractory metal nitride layer 4b is formed on the exposed top surface of the dielectric sublayer 11 to cover the exposed surface of the Cu-based conductor 5. This process may be termed the “second covering step”.

As the material of the layer 4b, the same refractory metal nitride as the nitride layer 4a is preferably used. Needless to say, a different refractory metal nitride may be used for the layer 4b. The layer 4b may be formed in the same way as the layer 4a to cover the exposed surface of the conductor 5.

In the process of forming the refractory metal nitride layer 4b, a mask (not shown) that covers selectively the unnecessary area (e.g., the exposed surface of the dielectric sublayer 11) may be used. In this case, after the nitride layer 4b is deposited, the mask is removed along with the layer 4b located thereon. However, to simplify the fabrication process sequence, it is preferred that the nitride layer 4b is formed without any mask, as shown in FIG. 2G.

The refractory metal nitride layer 4b thus deposited has a thickness of 2 to 50 nm on the top surface of the Cu-based line 5.

Following this, as shown in FIG. 2H, the refractory metal nitride layers 4a and 4b and the dielectric sublayer 11 are selectively removed by a CMP process until only the part of the refractory metal nitride layer 4b located on the conductor 5 is left (in other words, until the polished surface of the sublayer 11 is in approximately the same plane as the surface of the layer 4b). Thus, the refractory metal nitride layer 4a covers the two side surfaces and the bottom surface of the Cu-based conductor 5 while the refractory metal nitride layer 4b covers the top surface of the conductor 5. The combination of the refractory metal nitride layers 4a and 4b constitutes the cover layer 4. As a result, the composite wiring line 6 is formed by the Cu-based conductor 5 and the refractory metal nitride cover layer 4 that surrounds entirely the conductor 5.

To detect the time when the surface of the refractory metal nitride layer 4b and the surface of the dielectric sublayer 11 is in approximately the same plane, the change of a specific physical property or properties is measured or monitored during the CMP process. Two examples of the detection method are explained here.

The first example of the detection method is the use of a torque detector provided in the polishing apparatus for the CMP process, in which the change of the polishing torque is detected. If the refractory metal nitride layer 4b on the dielectric sublayer 11 is entirely removed and the underlying sublayer 11 begins to be polished, the polishing torque changes distinctly. Thus, it can be known that the entire removal of the nitride layer 4b on the sublayer 11 occurs at the time the torque distinctly changes.

The second example of the detection method is the use of an infrared (IR) light irradiator for irradiating IR light to the bottom surface of the substrate 2 and an IR light receiver for receiving the IR light reflected from the substrate 2. In this example, the change of the IR light reflected by the substrate 2 is detected. If the refractory metal nitride layer 4b on the dielectric sublayer 11 is entirely removed and the underlying sublayer 11 begins to be polished, the amount (i.e., intensity) of the IR light reflected by the substrate 2 changes distinctly. Thus, it can be known that the entire removal of the layer 4b on the sublayer 11 occurs at the time the IR light intensity distinctly changes.

The time when the surface of the nitride layer 4b and the surface of the dielectric sublayer 11 are in approximately the same plane is estimated to occur after a specific period of time has passed according to the thickness of the sublayer 11.

Through the above-described process steps, the wiring line 6 located in the first or lower wiring level is completed.

Next, as shown in FIG. 2I, a second dielectric layer 8A is formed on the exposed surface of the remaining refractory metal nitride layer 4b on the Cu-based conductor 5 and the exposed surface of the first dielectric layer 8 (i.e., the dielectric sublayer 11). The layer 8A may be formed in the same way as the first dielectric layer 9 used in the “first dielectric layer formation step”. This process may be termed the “second dielectric layer formation step”.

The second dielectric layer SA has typically a thickness of 0.6 μm to 1 μm. The layer 8A serves as an interlayer dielectric between the two wiring lines 6 located in the first and second (i.e., lower and upper) wiring levels in FIG. 1.

The wiring line 6 in the second or upper wiring level is formed by performing the same process steps (i.e., from the first covering step to the second dielectric layer formation step) as described for the wiring line 6 in the first or lower wiring level.

Thus, the semiconductor device 1 as shown in FIG. 1 having the two wiring lines 6 in the dielectric 3 is fabricated.

As seen from FIGS. 1 and 2I, the structure in FIG. 1 does not correctly accord with the structure in FIG. 2I. This is because FIG. 1 shows the schematic, simplified structure of the device 1. However, if the opposite side surfaces of the trench 12 are formed not to be tilted with respect to the imaginary plane of the bottom of the trench 12 (i.e., the opposite side surfaces of the trench 12 are perpendicular to the imaginary plane), the structure of the wiring line 6 accords with the structure shown in FIG. 1.

In the above-described first fabrication method, the “polishing step” for removing selectively the unnecessary Cu-based materials 13a and 14a is carried out just after the “partial filling step” for partially filing the trench 12 with the Cu-based materials 13 and 14, as shown in FIG. 2F. However, the “polishing step” may be carried out after the “second covering step” for depositing the refractory metal nitride layer 4b, as shown in FIG. 2G. In this case, the process steps are as follows.

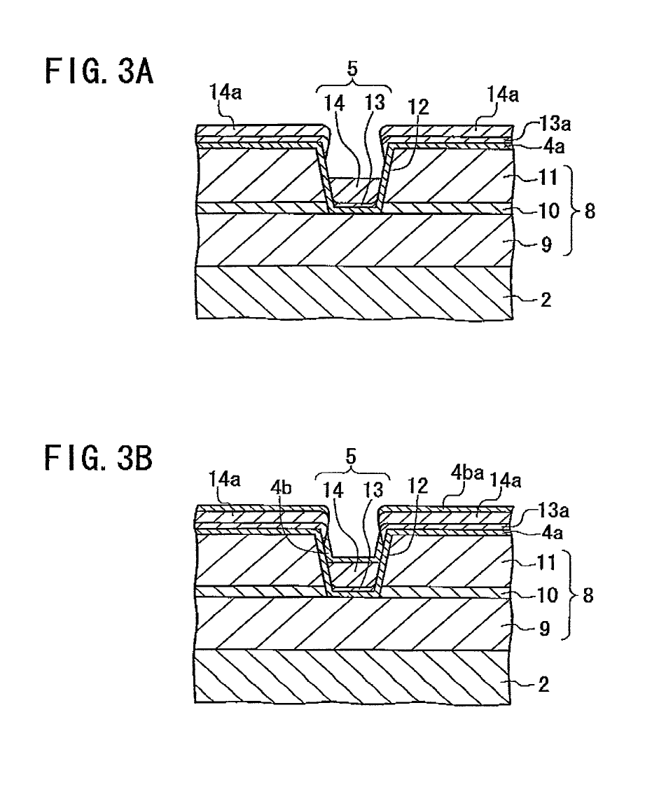

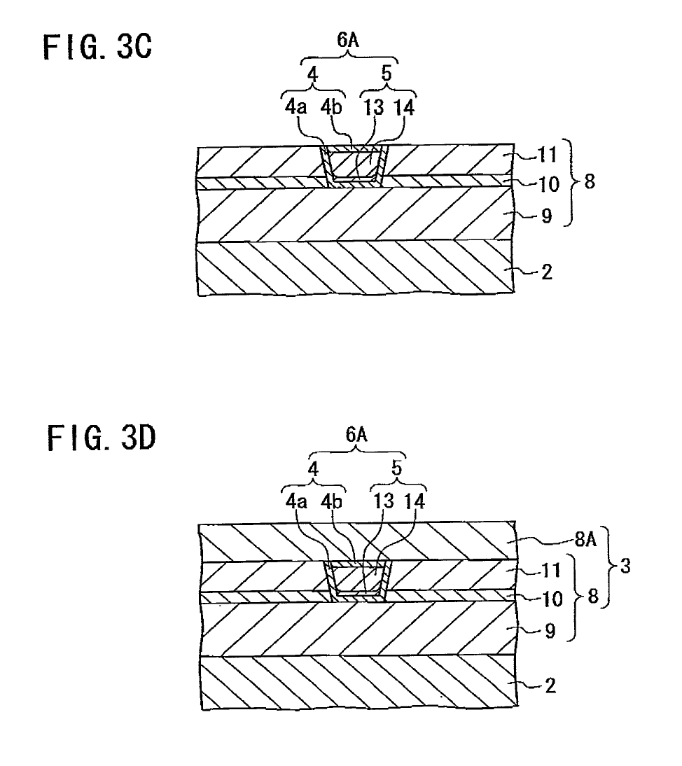

As shown in FIG. 3A, the structure shown in FIG. 2E is formed in the same process steps as those in the above-described method. Next, as shown in FIG. 3B, a refractory metal nitride layer 41b is formed on the exposed surface of the Cu-based material 14 in the trench 12. At this timer an unnecessary refractory metal nitride layer 4b a is formed on the Cu-based material 14a located outside the trench 12 and near the opening end of the trench 12 as well.

Subsequently, by a CMP process, the unnecessary nitride layer 4b a and the unnecessary Cu-based materials 13a and 14a and the part of the refractory metal nitride layer 4a located outside the trench 12 are selectively removed, exposing the surface of the first dielectric layer 8 (i.e., the dielectric sublayer 11). Moreover, the remaining nitride layers 4a and 4b and the dielectric sublayer 11 are selectively removed in the same CMP process until the polished surface of the sublayer 11 and the remaining nitride layer 4b on the Cu-based material 5 are approximately in the same plane.

As a result, as shown in FIG. 3C, the wiring line 6 in the first or lower wiring level is formed in the dielectric 3, where the line 6 comprises the Cu-based conductor 5 (which is formed by the Cu-based materials 13 and 14) and the cover layer 4 (which is formed by the refractory metal nitride layers 4a and 4b) surrounding the entire outer surface of the conductor 5.

Subsequently, as shown in FIG. 3C, a second dielectric layer 8A is formed on the exposed surface of the remaining refractory metal nitride layer 4b and the polished surface of the first dielectric layer 8 (i.e., the dielectric sublayer 11). Thus, through the second fabrication method, the same structure as shown in FIG. 2I is obtained. The following process steps are the same as those in the above-described first method.

Thus, the semiconductor device 1 shown in FIG. 1 can be fabricated in any one of the above-described first and second methods.

### Second Embodiment

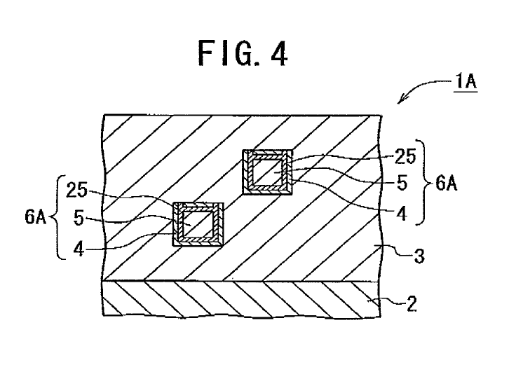

FIG. 4 shows a semiconductor device 1A according to a second embodiment of the invention, which has the same configuration as the device 1 according to the first embodiment except that a refractory metal layer 25 is additionally provided between the Cu-based conductor 5 and the refractory metal nitride cover layer 4. Therefore, the explanation on the same configuration is omitted here for simplification of description by attaching the same reference symbols as those in the device 1 to the same elements in FIG. 4.

With the device 1A according to the second embodiment, as shown in FIG. 4, two wiring lines 6A are formed to be apart from each other in the dielectric 3 on the substrate 2. One of the lines 6A is in the first or lower wiring level and the other is in the second or upper wiring level.

Each of the lines 6A is formed by the Cu-based conductor 5, the refractory metal layer 25, and the refractory metal nitride cover layer 4. The entire outer surface of the conductor 5 is covered with and contacted with the refractory metal cover layer 25. The entire surface of the cover layer 25 is further covered with and contacted with the refractory metal nitride cover layer 4.

Since the device 1A according to the second embodiment of FIG. 4 has the refractory metal layer 25 between the conductor 5 and the refractory metal nitride cover layer 4, there is an additional advantage that the Cu-based conductor 5 provides a better crystallinity to raise its electron migration resistance compared with the device 1 according to the first embodiment.

The refractory metal layer 25 may be made of any refractory metal. However, for example, titanium (Ti, melting point; 1667° C.), vanadium (V, melting point: 1915° C.), chromium (Cr, melting point: 1900° C.), zirconium (Zr, melting point: 1857° C.), niobium (Nb, melting point: 2468° C.), molybdenum (Mo, melting point: 1620° C.), hafnium (Hf, melting point: 2222° C.), tantalum (Ta, melting point: 2980° C.), or tungsten (W, melting point: 3380° C.) is preferably used It is more preferred that Ti, Ta, or W is used for the layer 25.

Generally, it a Cu-based conductor is covered with a refractory metal layer only in a dielectric, a problem may occur. For example, if the dielectric is made of a fluorine-containing dielectric (e.g., SiOF), the refractory metal layer is contacted with the dielectric 3 and thus, the refractory metal reacts with fluorine (F) contained in the dielectric 3. Therefore, a problem that the adhesion strength between the refractory metal layer and the dielectric degrades arises.

On the other hand, with the semiconductor device 1A according to the second embodiment, since the refractory metal layer 25 is entirely covered with the refractory metal nitride layer 4, the nitride layer 4 prevents the reaction between the refractory metal layer 25 and the dielectric 3. This means that the adhesion strength degradation between the metal layer 25 and the dielectric 3 will not arise. In other words, the adhesion strength between the metal layer 25 and the dielectric 3 is kept high.

Similar to the device 2 according to the first embodiment, the refractory metal nitride cover layer 4 is provided to cover entirely the Cu-based conductor 5. Therefore, even if a heat treatment process is repeated several times to form the wiring lines 6A in the different wiring levels the Cu-based conductor 5 itself and/or the dielectric 3 is/are prevented from degrading in characteristics. At the same time, there is an additional advantage that the property or characteristics of the conductor 5 and the dielectric 3 is kept unchanged even under severe fabrication process conditions.

With the semiconductor device 1A according to the second embodiment, like the device 1 according to the first embodiment, even if the distance between the adjoining wiring lines 6A is shortened, the increase of the parasitic wiring capacitance is suppressed effectively, thereby raising the operation speed of the circuitry provided on the substrate 2 and electrically connected through the wiring lines 6A.

Also, the diffusion of the Cu atoms contained in the conductor 5 into the dielectric 3 and the oxidation of the conductor 5 itself are effectively suppressed or prevented. As a result, the malfunction or incorrect operation of the circuits in the device 1A can be prevented.

Furthermore, the adhesion strength between the conductor 5 and the cover layer 4 is improved.

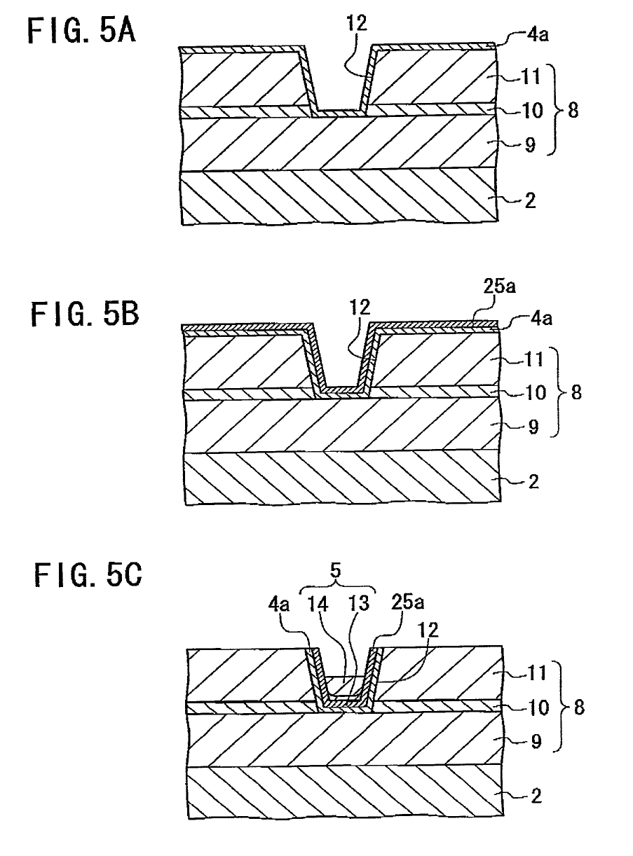

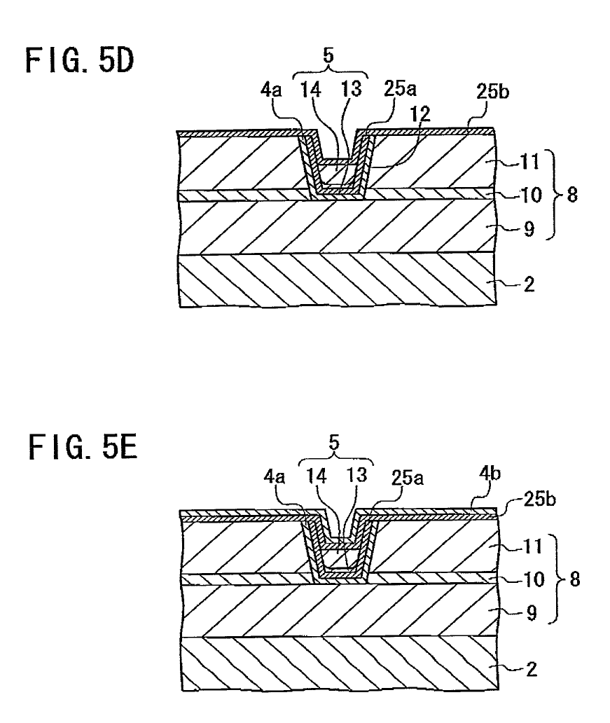

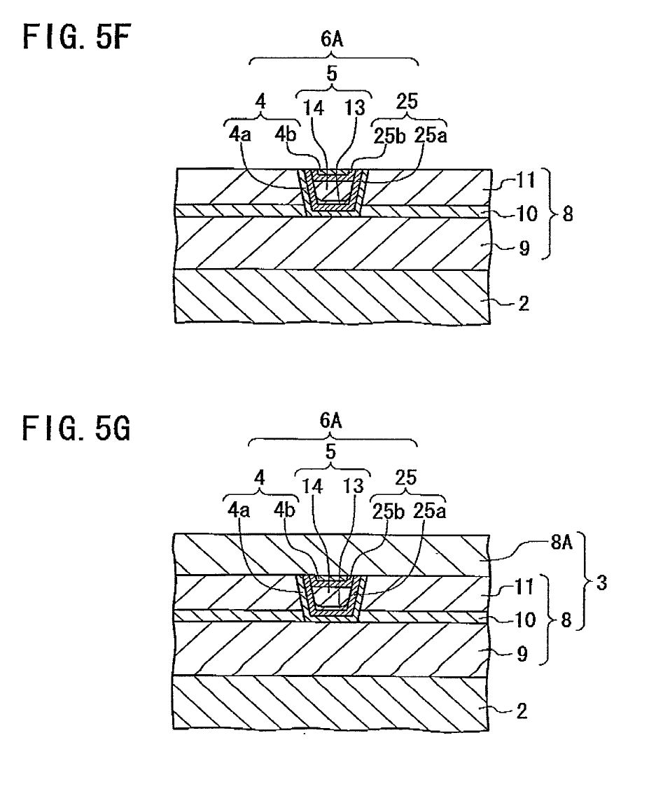

Next, a method of fabricating the semiconductor device 1A according to the second embodiment is explained below with reference to FIGS. 5A to 5G.

First, as shown in FIG. 5A, the same structure as shown in FIG. 2C is formed in the same way as the first embodiment. At this stage, the trench 12 is formed in the dielectric sublayer 11 and the etch stop layer 10 while the nitride layer 4a of a refractory metal is formed to cover the side and bottom faces of the trench 12 and the surface of the dielectric sublayer 11.

Next, as shown in FIG. 5B, a refractory metal layer 25a is formed on the nitride layer 4a. Any one of the refractory metals identified as above (i.e., Ti, V, Cr, Zr, Nb, Mo, Hf, Ta, or W) may be used for the layer 25a. The metal layer 25a is typically formed by a DC or RF sputtering process.

Then, as shown in FIG. 5C, in the same way as the first embodiment, the Cu-based conductor 5 is formed by the Cu-based materials 13 and 14 in the trench 12. Thereafter, the unnecessary materials 13a and 14a on the dielectric sublayer 11 are selectively removed in the same way as the first embodiment, thereby exposing the surface of the dielectric sublayer 11.

Another refractory metal layer 25b is then formed on the exposed surface of the dielectric sublayer 11 and the exposed surface of the Cu-based material 14, as shown in FIG. 5D. Any one of the above-identified refractory metals (i.e., Ti, V, Cr, Zr, Nb, Mo, Hf, Ta, or W) may be used for the layer 25b. It is preferred that the same refractory metal as used for the layer 25a is used for the layer 25b. The layer 25b is typically formed by a DC or RF sputtering process.

Subsequently, a refractory metal nitride layer 4b is formed on the refractory metal layer 25b in the same way as the first embodiment, as shown in FIG. 5E.

Then, to remove the unnecessary nitride layers 4a and 4b and the unnecessary metal layers 25a and 25b, a CMP process is carried out until the nitride layer 4b is left over the Cu-based conductor 5 only in the trench 12, as shown in FIG. 5F. Thus, the wiring line 6A in the first or lower wiring level, which comprises the Cu-based conductor 5, the refractory metal layer 25, and the refractory metal nitride layer 4, is formed in the trench 12.

Following this, as shown in FIG. 5G, the second dielectric layer 8A is formed on the exposed surface of the dielectric sublayer 11 and the remaining nitride layer 4b. Typically, the dielectric layer 8A has a thickness of 0.6 μm to 1 μm. The layer 8A serves as an interlayer dielectric layer between the wiring lines 6A located in the first and second wiring levels.

The wiring line 6A in the upper wiring level is formed in the same way as the wiring line 6A in the lower wiring level by repeating the set from the “first covering step” to the “second dielectric formation step”.

Thus, the semiconductor device 1A according to the second embodiment in FIG. 4 having the two wiring lines 6A in the dielectric 3 is fabricated.

As seen from FIGS. 4 and 5G, the structure in FIG. 4 does not correctly accord with the structure in FIG. 5G. This is because FIG. 4 shows the schematic, simplified structure of the device 1A. However, if the inner walls of the trench 12 are formed not to be tilted with respect to the imaginary plane of the bottom of the trench 12, the structure of the wiring line 6A accords with that shown in FIG. 4.

### Third Embodiment

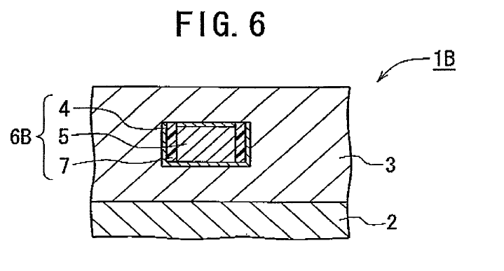

FIG. 6 shows a semiconductor device 1B according to a third embodiment of the invention, which has the same configuration as the device 1 according to the first embodiment except that an inner dielectric 7 is additionally provided between the cu-based conductor 5 and the refractory metal nitride cover layer 4. Therefore, the explanation on the same configuration is omitted here for simplification of description by attaching the same reference symbols as those in the device 1 to the same elements in FIG. 6

With the device 1B according to the third embodiment, as shown in FIG. 6, a wiring line 6B is formed in the dielectric 3 on the substrate 2. The line 6B is located in the first or lower wiring level while a wiring line B located in the second or upper wiring level is omitted in FIG. 6.

The inner dielectric layer 7 is located at each side of the conductor 5 in the trench 12 between the conductor 5 and the cover layer 4. Due to the existence of the layer 7, the Cu-based material is prevented from growing on each side face of the trench 12 in the process of partially filing the trench 12 with the Cu-based material for the conductor 5. The layer 7 typically has a thickness of 10 nm to 50 nm.

The inner dielectric layer 7 may be made of any dielectric material. However, it is preferred that the layer 7 is made of the same material for the dielectric 3. Preferably, SiO₂ is used for the layer 7.

It is needless to say that the device 1B according to the third embodiment has the same advantages as those in the first embodiment.

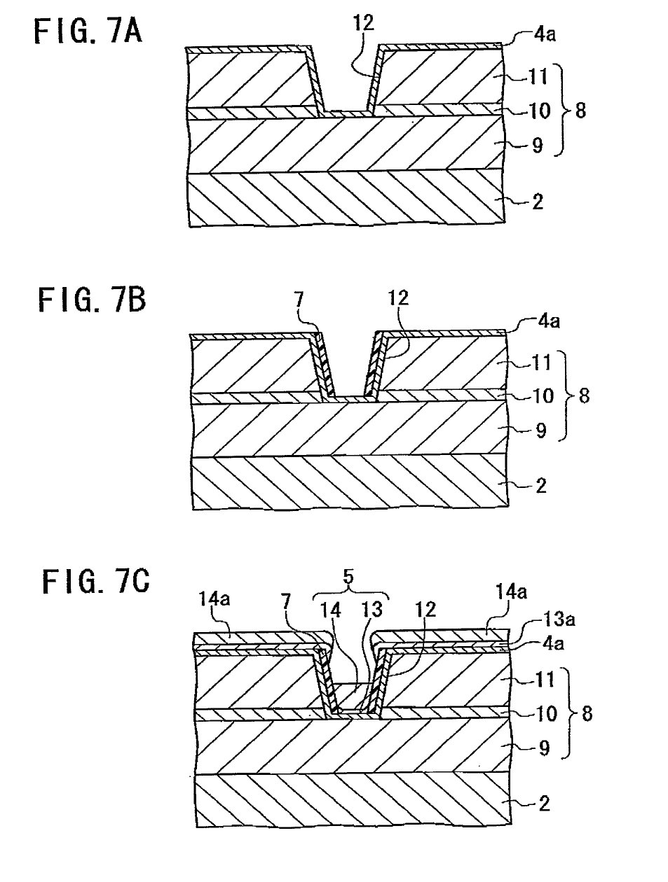

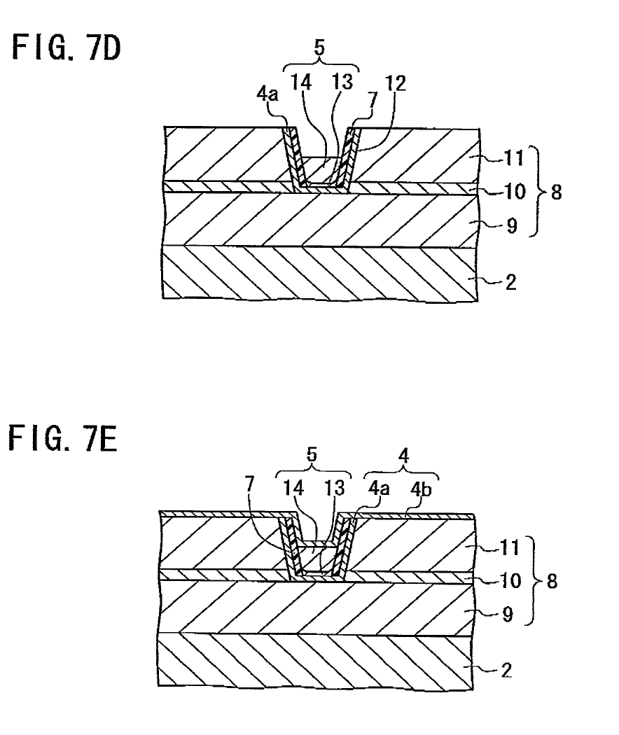

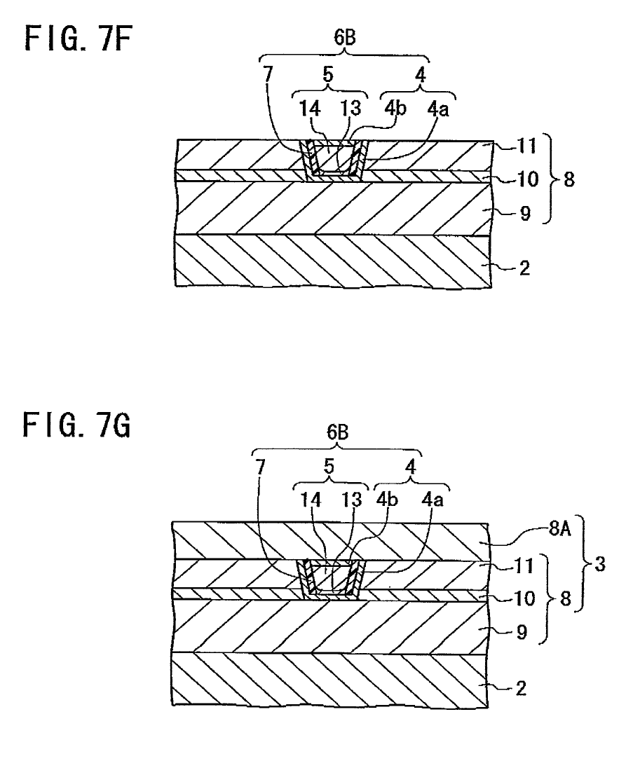

Next, a method of fabricating the semiconductor device ID according to the third embodiment is explained below with reference to FIGS. 7A to 7G.

First, as shown in FIG. 7A, the same structure as shown in FIG. 2C is formed in the same way as the first embodiment. At this stage, the trench 12 is formed in the dielectric sublayer 11 and the etch stop layer 10 while the nitride layer 4a of a refractory metal is formed to cover the side and bottom faces of the trench 12 and the surface of the dielectric sublayer 11.

Next, as shown in FIG. 7B, the inner dielectric layer 7 is formed on the nitride layer 4a over the substrate 2. Then, the layer 7 is selectively removed by an anisotropic etching process, thereby leaving the layer 7 on each side of the trench 12. The reason why the layer 7 is removed at the bottom of the trench 12 is to form a growth point of Cu used in the following process of depositing the Cu-based conductor 5. In this process, the part of the layer 7 located on the dielectric sublayer 11 outside the trench 12 is removed as well. However, the part of the layer 7 located on the dielectric sublayer 11 outside the trench 12 may be left.

Like the dielectric sublayer 9, the inner dielectric layer 7 is typically formed by a thermal oxidation or plasma-enhanced CVD process using SiH₄ and N₂O. However, the layer 7 may be formed by a thermal or optical CVD process, or a plasma-enhanced CVD process using TEOS and oxygen (O). The material for the layer 7 may be the same as or different from the dielectric sublayer 9 or 11. For example, SiO₂, SiOF, or HSQ is preferably used. The thickness of the layer 7 is typically 10 nm to 50 nm.

Then, as shown in FIG. 7C, the Cu-based materials 13 and 14 are deposited on the remaining nitride layer 4a and the remaining dielectric layer 7 in the trench 12. In this case, both sputtering and plating processes are used in the same way as the first embodiment. Thus, the Cu-based conductor 5 is formed by the materials 13 and 14 in the trench 12. In the processes, the unnecessary Cu-based material 13a is formed on the nitride layer 4a outside the trench 12 and on the nitride layer 4a in the vicinity or the top opening of the trench 12. The unnecessary Cu-based material 14a is formed on the material 13a outside the trench 12 and in the vicinity or the top opening of the trench 12.

Thereafter, the unnecessary Cu-based materials 13a and 14a and the unnecessary nitride layer 4a deposited outside or near the opening of the trench 12 are selectively removed, exposing the surface of the first dielectric layer 8 (i.e., the dielectric sublayer 11), as shown in FIG. 7D. Preferably, this removing process is carried out by a CMP process. It is important that the exposed surface of the sublayer 11 is higher than the exposed top surface of the conductor 5.

Furthermore, as shown in FIG. 7E, a nitride layer 4b of refractory metal is formed over the substrate 2. At this time, the nitride layer 4b is formed on the top surface of the Cu-based conductor 5 and the exposed surfaces of the dielectric layer 7 and the dielectric sublayer 11. The nitride layer 4b has a thickness of 2 nm to 50 nm on the top of the Cu-based conductor 5.

Following this, as shown in FIG. 7F, the refractory metal nitride layers 4a and 4b and the dielectric sublayer 11 are selectively removed by a CMP process until only the part of the nitride layer 4b located on the conductor 5 is left (in other words, until the surface of the layer 4b and the surface of the sublayer 11 are in approximately the same plane) . The combination of the refractory metal nitride layers 4a and 4b constitutes the cover layer 4. Thus, the composite wiring line 6 is formed by the Cu-based conductor 5, the inner dielectric layer 7, and the refractory metal nitride cover layer 4.

Through the above-described process steps, the wiring line 6B located in the first or lower wiring level is completed.

Furthermore, as shown in FIG. 7G, an interlayer dielectric layer 8A is formed on the exposed surface of the first dielectric layer 8 (i.e., the dielectric sublayer 11) and the exposed surface of the remaining refractory metal nitride layer 4b. The layer 8A may be formed in the same way as the dielectric sublayer 9. The layer 8A has typically a thickness of 0.6 μm to 1 μm. The layer 8A serves as an interlayer dielectric between the two wiring lines 6B located in the first and second (i.e., lower and upper) wiring levels.

The wiring line 6B in the second or upper wiring level is formed by performing the same process steps as described for the wiring line 6B in the first or lower wiring level.

As a result, the semiconductor device 1B according to the third embodiment shown in FIG. 6 having the two wiring lines 68 in the dielectric 3 is fabricated.

### EXAMPLES

To confirm the advantages of the invention, the inventor fabricated practically the semiconductor devices 1B according to the third embodiment and tested the same as referred below.

### Example 1

As the example 1, inventive semiconductor devices were fabricated by the method according to the third embodiment in the following way.

In the first dielectric formation step (FIG. 2A) a silicon (Si) substrate was used as the substrate 2 and then, a SiO₂ layer (0.1 μm in thickness) was formed on the surface of the Si substrate 2 as the interlayer dielectric sublayer 9 by an atmospheric-pressure CVD process. Next, a SiON layer (0.1 μm in thickness) was formed on the surface of the sublayer 9 as the etch stop layer 10 by an atmospheric-pressure CVD process. Thereafter, a SiO₂ layer (0.5 μm in thickness) was formed on the surface of the etch stop sublayer 10 as the dielectric sublayer 11 by a plasma-enhanced CVD process.

In the subsequent trench formation step (FIG. 2B), a patterned mask was formed on the SiO₂ layer 11 by a photolithography process. Then, using the mask thus formed, the SiO₂ layer 11 was selectively etched by a reactive ion etching process using gaseous CF₄, forming the trenches 12 with the same inverted trapezoidal shape in the SiO₂ layer 11. Each of the trenches 12 had a depth of 0.5 μm and a width of 0.3 μm at its opening end. At this time, the etch stop layer 10 was etched as well and thus, the surface of the SiO₂ layer 9 was exposed in the trenches 12.

In the subsequent first covering step (FIG. 7A) a tantalum nitride (TaN) layer (20 nm in thickness) was formed on the surface of the SiO₂ layer 11 as the refractory metal nitride layer 4a by a sputtering process.

In the subsequent inner dielectric formation step (FIG. 7B), a SiO₂ layer (10 nm in thickness) for the inner dielectric 7 was formed on the surface of the TaN layer 4a by a plasma-enhanced CVD process. Then, the SiO₂ layer 7 thus formed was selectively and anisotropically etched by a reactive ion etching process using gaseous CF₄ under the condition that the supplied electric power was 1000 W and the ambient pressure was 10 Pa, thereby selectively removing the SiO₂ layer 7 at the bottom of each trench 12 and on the surface of the TaN layer 4a. Thus, the SiO₂ layer 7 was left on the opposite side faces of each trench 12 while the TaN layer 4a is exposed at the bottom of each trench 12 and on the surface of the SiO₂ layer 11. The SiO₂ layer 7 thus left was used as the inner dielectric.

In the subsequent partial filling step (FIG. 7C), Cu was deposited in the trenches 12 as the Cu-based material 13 by a sputtering process. The Cu 13 thus deposited had a specific thickness in the range from 2 nm to 50 nm. At this time, the unnecessary Cu 13a was deposited on the TaN layer 4a outside the trenches 12.

Then, Cu was further deposited on the Cu 13 as the Cu-based material 14 in the trenches 12 by a plating process using a plating solution of Cu, in which the current density was set at 20 to 30 mA/cm². The Cu 14 thus deposited had a specific thickness in the range from 2 nm to 50 nm. At this timer the unnecessary Cu 14a was deposited on the unnecessary Cu 13a outside the trenches 12.

Following this, the unnecessary Cu 13a and 14a and the parts of the SiO₂ layer 7 and the nitride layer 4a were selectively removed by a CMP process using a silica-containing slurry under the polishing condition that the applied load was 2 psi to 10 psi and the rotation rate was 30 rpm to 150 rpm. The state at this stage was shown in FIG. 7D.

In the subsequent second covering step (FIG. 7E), a TaN layer was deposited on the remaining Cu 14 in the trenches 12 as the refractory metal nitride layer 4b by a sputtering. The TaN layer 4b was deposited on the exposed surface of the SiO₂ layer 11 as well. The TaN layer 4b thus deposited had a specific thickness in the range from 5 nm to 20 nm.

Furthermore, to remove the unnecessary TaN layer 4b and the unnecessary part of the SiO₂ layer 11 and to adjust the height of the resultant wiring line 6B at 0.4 μm, a CMP process was carried out using a silica-containing slurry under the polishing condition that the applied load was 2 psi to 10 psi and the rotation rate was 30 rpm to 150 rpm. This CMP process was continued until the surface of the TaN layer 4b on the Cu 14 and the polished surface of the SiO₂ layer 11 are approximately in the same plane. The state at this stage was shown in FIG. 7F.

In the subsequent second dielectric formation step (FIG. 7G), a SiO₂ layer was formed as the second dielectric layer 8A on the resultant surface of the SiO₂ layer 11 and the resultant surface of the TaN layer 4b in the same way as the first dielectric layer formation step.

Through the above-described process steps, the semiconductor devices IS according to the third embodiment were fabricated. In the devices 1B thus fabricated, the ratio of the wiring line width and the wiring line interval was 1:1, the wiring line pitch was 0.4 μm, the thickness of each wiring line 6B was 0.4 μm, and all the SiO₂ layers used therein had a relative dielectric constant of 4.1.

Additionally, through the same process steps as explained above in the Example 1, the semiconductor devices 1B having the ratio of the wiring line width and the wiring line interval of 1:1, the wiring line pitch of 0.6 μm, the thickness of each wiring line 6B of 0.4 μm were fabricated. Moreover, the semiconductor devices 1B having the ratio of the wiring line width and the wiring line interval of 1:1, the wiring line pitch of 0.8 μm, the thickness of each wiring line 6B of 0.4 μm were fabricated.

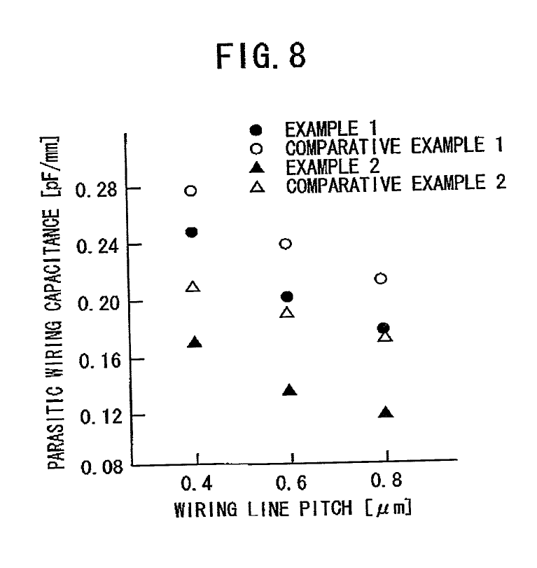

The inventor measured the parasitic wiring capacitance of these inventive semiconductor devices 1B with different wiring line pitches of of 0.4 μm, 0.6 μm, and 0.8 μm using a known method. The result of this measurement is shown in FIG. 8.

### Comparative Example 1

As the comparative example 1, conventional semiconductor devices were fabricated in the same way as the example 1, except that the TaN layers 4a and 4b were not formed and that a SiN layer (0.05 μm in thickness) was formed on the top of each Cu conductor 5 by a plasma-enhanced CVD process. In all the conventional devices thus fabricated, the ratio of the wiring line width and the wiring line interval was 1:1 and the thickness of each wiring line was 0.4 μm. However, they had different wiring line pitches of 0.4 μm, 0.6 μm, and 0.8 μm.

The inventor measured the parasitic wiring capacitance of these conventional semiconductor devices with different wiring line pitches using the same method as used in the example 1. The result of this measurement is shown in FIG. 8.

### Example 2

As the example 2, inventive semiconductor devices 1B were fabricated in the same way as the example 1, except that an organic dielectric layer with a low relative dielectric constant was formed as the dielectric sublayer 9 instead of the SiO₂ layer. In all the devices thus fabricated, the ratio of the wiring line width and the wiring line interval was 1:1 and the thickness of each wiring line was 0.4 μm, However, they had different wiring line pitches of 0.4 μm, 0.6 μm, and 0.8 μm. The organic dielectric layer 9 was formed by coating a BCB layer (0.4 μm in thickness) on the surface of the substrate 2 by a known spin-coating process and by annealing the BCB layer thus formed. The BCB layer had a relative dielectric constant of 2.6.

The inventor measured the parasitic wiring capacitance of these inventive semiconductor devices 1B with different wiring line pitches using the same method as used in the example 1. The result of this measurement is shown in FIG. 8.

### Comparative Example 2

As the Comparative example 2, conventional semiconductor devices were fabricated in the same way as the example 1, except that an organic dielectric layer with a low relative dielectric constant was formed as the dielectric sublayer 9 instead of the SiO₂ layer, that the TaN layers 4a and 4b were not formed, and that a SiN layer (0.05 μm in thickness) was formed on the top of each Cu conductor 5 by a plasma-enhanced CVD process. In all the devices thus fabricated, the ratio of the wiring line width and the wiring line interval was 1:1 and the thickness of each wiring line was 0.4 μm. However, they had different wiring line pitches of 0.4 μm, 0.6 μm, and 0.8 μm.

The inventor measured the parasitic wiring capacitance of these conventional semiconductor devices with different wiring line pitches using the same method as used in the example 1. The result of this measurement is shown in FIG. 8.

As seen from FIG. 8, the parasitic wiring capacitance in the example 1 is less than the comparative example 1 even when the wiring line pitch is at 0.4 μm, 0.6 μm, and 0.8 μm. Also, it is also seen that when the wiring line pitch is increased, the decreasing rate or the parasitic wiring capacitance in the example 1 is greater than that in the comparative example 1.

Similarly, the parasitic wiring capacitance in the example 2 is less than the comparative example 2 even when the wiring line pitch is at 0.4 μm, 0.6 μm, and 0.8 μm. Also, it is also seen that when the wiring line pitch is increased, the decreasing rate of the parasitic wiring capacitance in the example 2 is greater than that in the comparative example 2.

Thus, it was confirmed that the decreasing rate of the parasitic wiring capacitance with the increasing wiring line pitch increases due to covering the Cu conductor 5 with the TaN cover layer 6B.

### Example 3

As the example 3, inventive semiconductor devices 1A according to the second embodiment were fabricated in the same way as the example 1, except that the tilt angle θ of the inner side faces of each trench 12 was set at 65°, 75°, 80°, 85°, and 90° with respect to the imaginary plane of the bottom of the trench 12, and that each Cu conductor 5 was covered with a Ta layer as the refractory metal layer 25 and the Ta layer 25 is covered with a TaN layer as the refractory metal nitride layer 4. In the devices 1A thus fabricated, the wiring lines 6A had the same width of 0.3 μm and the same thickness of 0.3 μm.

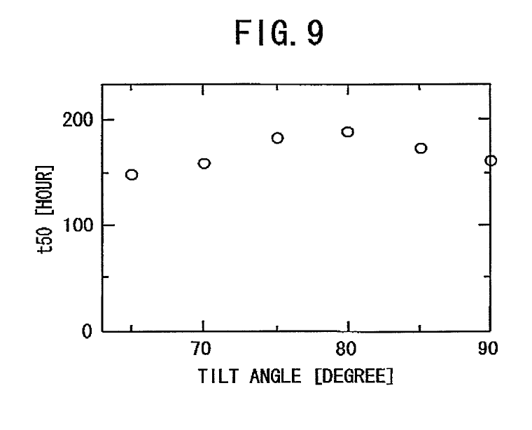

An electromigration (EM) lifetime test was conducted to the devices 1A thus fabricated and their EM resistance was evaluated. In the EM lifetime test, the current density was set at 3×10⁶ A/cm² and the ambient temperature was set at 300° C. The result of this test is shown in FIG. 9. It is seen from FIG. 9 that the preferred tilt angle θ is 70° to 85°.

### Comparative Example 3

For the comparative example 3, the fabrication processes were carried out from the first dielectric layer formation step (FIG. 2A) to the second covering step (FIG. 7E) in the same way as the example 1, except that each Cu conductor 5 was covered with a SiN layer (50 nm in thickness). Thereafter, the SiN layer and the dielectric sublayer 11 was exposed by a CMP process. The ratio of the wiring line width and the wiring line pitch was 1:1 and the wiring line pitch was 0.4 μm.

At this stage, the inventor evaluated the adhesion strength of the SiN layer by the known Scotch tape test. In this test, the SiN layer was divided into 10×10 (=100) square parts each having the same area of 1 mm².Then, a specific adhesion tape was adhered to the SiN layer thus divided and detached therefrom. The adhesion strength was evaluated by the number of the detached square parts along with the tape thus separated. The result of the Scotch tape test is shown in the following Table 1.

Moreover, as the comparative example 3, conventional semiconductor devices were fabricated in the same way as the example 1, except that each Cu conductor 5 was covered with a SiN layer (50 nm in thickness). In all the conventional devices thus fabricated, the ratio of the wiring line width and the wiring line interval was 1:1 and the thickness of each wiring line was 0.4 μm.

The inventor evaluated the diffusion level of Cu atoms in the Cu conductor 5 of these conventional semiconductor devices by the current leakage test (i.e. , BT test). The result of this evaluation is shown in Table 1.

### Comparative Example 4

As the comparative example 4, conventional semiconductor devices were fabricated in the same way as the comparative example 3, except that a SiO₂ layer was formed instead of the SiN layer that covers the Cu conductor 5.

The inventor conducted the same Scotch tape test and the same current leakage test as used in the comparative example 3 for these conventional semiconductor devices. The result of this test is shown in Table 1.

### Example 4

As the example 4, the fabrication processes were carried out from the first dielectric layer formation step (FIG. 2A) to the second covering step (FIG. 7E) in the same way as the example 1. At this stage, the surface of the TaN layer 4b and the surface of the SiO₂ sublayer 11 were in approximately the same plane. The inventor evaluated the adhesion strength of the TaN layer 4b by the same Scotch tape test as conducted in the comparative example 3. The result of the Scotch tape test is shown in Table 1.

Also, the inventor evaluated the diffusion level of Cu atoms in the Cu conductor 5 of these inventive semiconductor devices by the current leakage test (i.e., BT test). In these devices, the ratio of the wiring line width and the wiring line pitch was 1:1 and the wiring line pitch was 0.4 μm. The result of this test is shown in Table 1.

TABLE 1

| | Scotch Tape Test | Current Leakage Test (A) |
|---|---|---|
| Comparative Example 3 | 35 | in the order of 10⁻¹⁰ |
| Comparative Example 4 | 0 | <10⁻¹² |
| Example 4 | 0 | <10⁻¹² |

As seen from Table 1, it is confirmed that when the top of the Cu conductor 5 is covered with the TaN layer 4b, the adhesion strength (or, adhesion property) of the TaN layer 4b is raised and the current leakage is lowered compared with the case where the top of the Cu conductor 5 is covered with the SIN layer.

### Example 5

The same EM lifetime test as used in the example 3 was conducted to the inventive semiconductor devices fabricated in the example 1, thereby evaluating their EM resistance. The result of this test is shown in Table 2.

Also, as the example 5, inventive semiconductor devices were fabricated in the same way as the example 1, except that the TaN layer 4b was replaced with a titanium nitride (TIN) layer or a tungsten nitride (WN) layer. Then, the same EM lifetime test was conducted to the devices thus fabricated. The result of this test is shown in Table 2.

Moreover, inventive semiconductor devices were fabricated in the same way as the example 1, except that the Cu conductor 5 was covered with a Ta layer as the refractory metal layer 25 and then, the Ta layer 25 was covered with a TaN layer as the refractory metal nitride layer 4, instead of the TaN layer 4b. Then, the same EM lifetime test was conducted to the devices thus fabricated. The result of this test is shown in Table 2.

TABLE 2

| | EM test result, |
|---|---|
| | t50 (hour) |
| TiN layer covers entirely Cu conductor | 125 |
| TaN layer covers entirely Cu conductor | 163 |
| Ta layer covers entirely Cu conductor and | 185 |
| TaN layer covers the Ta layer | |
| WN layer covers entirely Cu conductor | 83 |

As seen from Table 2, the EM lifetime test for these inventive devices provided a good result. Also, it is seen from Table 2 that when the Ta layer covered the Cu conductor and the TaN layer covered the Ta layer, the EM resistance was improved compared with the case where only the TaN layer covers the Cu conductor.

While the preferred forms of the present invention have been described, it is to be understood that modifications will be apparent to those skilled in the art without departing from the spirit of the invention. The scope of the present invention, therefore, is to be determined solely by the following claims.

What is claimed is:

1. A semiconductor device comprising:
(a) a substrate having a surface;
(b) a dielectric formed over the surface of the substrate; and
(c) a wiring line buried in the first dielectric layer;
the wiring line including a Cu-based conductor and a first cover layer covering an outer surface of the conductor;
the first cover layer being made of refractory metal nitride.

2. The device according to claim 1, wherein the first cover layer is made of nitride of at least one selected from the group consisting of titanium (Ti), tantalum (Ta), and tungsten (W).

3. The device according to claim 1, further comprising a second cover layer provided between the conductor and the first cover layer;
wherein the second cover layer covers partially or entirely the outer surface of the conductor, the second cover layer being made of refractory metal.

4. The device according to claim 1, further comprising a third cover layer provided between the conductor and the first cover layer;
wherein the third cover layer covers entirely or partially the outer surface of the conductor, the third cover layer being made of dielectric.

5. The device according to claim 4, wherein the third cover layer covers the outer surface of the conductor at its each side.

6. The device according to claim 1, further comprising a second cover layer provided between the conductor and the first cover layer and a third cover layer provided between the conductor and the first cover layer;
wherein the second cover layer covers partially or entirely the outer surface of the conductor, the second cover layer being made of refractory metal;
and wherein the third cover layer covers entirely or partially the outer surface of the conductor, the third cover layer being made of dielectric.

7. The device according to claim 1, wherein the dielectric formed over the surface of the substrate is made of inorganic material and has a relative dielectric constant ranging from 1.6 to 9.

8. The device according to claim 1, wherein the dielectric formed over the surface of the substrate is made of organic material and has a relative dielectric constant of 16 to 3.

9. The device according to claim 1, wherein the wiring line has a damascene structure.

10. The device according to claim 1, wherein the dielectric in which the wiring line is buried has a composite structure comprising a first dielectric layer, an etch stop layer formed on the first dielectric layer, and a second dielectric layer formed on the etch stop layer;
and wherein the bottom of the first cover layer is approximately in a same level as an upper surface of the first dielectric layer;
and wherein the top of the first cover layer is approximately in a same level as an upper surface of the second dielectric layer.

11. The device according to claim 1, wherein the dielectric in which the trench has inner side faces tilted at an angle of 70° to 85° with respect to an imaginary plane of a bottom of the trench.

12. A method of fabricating a semiconductor device, comprising the steps of:
(a) forming a first dielectric layer over a surface of a substrate;
(c) forming a trench in the first dielectric layer;
(d) covering an inner surface of the trench with a first nitride of refractory metal;
(e) forming a Cu-based conductor on the first nitride of refractory metal in the trench;
(f) covering a top surface of the conductor in the trench with a second nitride of refractory metal;
(g) polishing the first dielectric layer until a polished surface of the first dielectric layer is approximately in a same level as a surface of the second nitride of refractory metal that covers the top surface of the conductor in the trench; and
(h) forming a second dielectric layer on the polished surface of the first dielectric layer to cover the surface of the second nitride of refractory metal in the trench;
wherein the Cu-based conductor is entirely covered with the first nitride of refractory metal and the second nitride of refractory metal in the trench;
and wherein the Cu-based conductor, the first nitride of refractory metal, and the second nitride of refractory metal constitute a Cu-based wiring line.

13. The method according to claim 12, wherein the trench is formed to have inner side faces tilted an angle of 70° to 85° with respect to an imaginary plane of a bottom of the trench in the step (c).

14. The method according to claim 12, wherein in the step (e) of forming the Cu-based conductor on the first nitride of refractory metal in the trench, part of the conductor is deposited by sputtering and then, the remaining conductor is deposited by plating.

15. The method according to claim 12, wherein in the step (e) of forming the Cu-based conductor, the conductor is formed in such a way that the conductor has a height less than a depth of the trench.

16. The method according to claim 12, wherein in the step (g) of polishing the first dielectric layer, a CMP process is used;
and wherein end detection of the CMP process is performed by detection of polishing of the first dielectric layer after unnecessary second nitride of refractory metal deposited on the first dielectric layer is completely removed.

17. The method according to claim 12, wherein in the step (d) of covering the inner surface of the trench, nitride of at least one selected from the group consisting of titanium (Ti), tantalum (Ta) and tungsten (W) is used as the first nitride of refractory metal.

18. The method according to claim 12, further comprising a step of depositing a first refractory metal layer on the inner surface of the trench between the step (c) of forming the trench and the step (d) of covering the inner surface of the trench;
wherein the first nitride of refractory metal is deposited on the first refractory metal layer in the step (d);
and wherein the first refractory metal layer is used for forming a second cover layer that covers partially or entirely the Cu-based conductor.

19. The method according to claim 18, further comprising a step of depositing a second refractory metal layer on the top surface of the conductor between the step (e) of forming the Cu-based conductor and the step (f) of polishing the first dielectric layer;
wherein the second refractory metal layer is located on the top surface of the conductor in the trench;
and wherein the first and second refractory metal layers form the second cover layer that covers entirely the Cu-based conductor.

20. The method according to claim 12, further comprising a step of selectively depositing a dielectric on the first nitride of refractory metal in the trench is added between the step (d) of covering the top surface of the conductor and the step (e) of forming the Cu-based conductor;
wherein the dielectric thus deposited is located at each side of the Cu-based conductor in the trench to expose the bottom of the trench;
and wherein the dielectric is used for forming a third cover layer that covers partially or entirely the Cu-based conductor.

21. The method according to claim 20, wherein the step of selectively depositing the dielectric on the first nitride of refractory metal includes a sub-step of depositing the dielectric on the first nitride of refractory metal and a sub-step of selectively etching part of the dielectric at the bottom of the trench.

22. The method according to claim 12, wherein the first cover layer is made of nitride of at least one selected from the group consisting of titanium (Ti), tantalum (Ta), and tungsten (W).

23. The method according to claim 12, wherein the first dielectric layer formed over the surface of the substrate is made of inorganic material and has a relative dielectric constant ranging from 1.6 to 9.

24. The method according to claim 12, wherein the first dielectric layer is made of organic material and has a relative dielectric constant of 1.6 to 3.
